(19) United States
(12) Patent Application Publication
(10) Pub. No.: US 2009/0218124 A1
(43) Pub. Date: Sep. 3, 2009

(54) METHOD OF FILLING VIAS WITH FUSIBLE METAL

(75) Inventors: JAROSLAW A. MAGERA, PALATINE, IL (US); BRUCE C. DEEMER, CRYSTAL LAKE, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 12/038,891

(22) Filed: Feb. 28, 2008

(51) Int. Cl. H05K 1/00; H05K 3/42

(52) U.S. Cl. 174/263; 29/852

(57) ABSTRACT

A method is disclosed in which a blind via in a PCB is filled. The vias are plated with a conductor and then with a fusible metal of lower melting point than the conductor. The plated vias are covered with a photoresist and the fusible metal is removed at locations on the PCB other than where the photoresist is disposed. The photoresist is removed and flux is provided on the PCB before the PCB is heated. The heated fusible metal flows into the via.

### TECHNICAL FIELD

The present application relates to vias. In particular, the application relates to method of filling vias with a fusible metal.

### BACKGROUND

As electronics is being increasingly miniaturized, complex, and faster, the circuitry in printed circuit boards (PCBs) in the electronics is becoming correspondingly smaller, more complex, and faster. This has led to multilayer PCBs in which the PCB contains alternating layers of metal and insulating material (dielectric). Buried metal layers contact circuitry formed by the top or bottom (surface) metal layer and components attached to the surface metal layer through a via. A via can either be a through hole, which extends through the entire PCB between the surface metal layers on the PCB surfaces, a blind via, which extends from the surface metal layer to one of the buried layers, or a buried via that connects between buried layers but does not extend all the way through the PCB. The buried layer permits efficient routing between circuitry and components disposed at different locations in the PCB without crowding circuit traces along either surface. The use of buried layers thus increases the number of components that can be disposed on the surface by decreasing the real estate on the surface used for connections.

In general, the components are permanently attached to the surface of the PCB using solder. FIG. 1 illustrates a cross-sectional view of a PCB 100 printed with solder paste 220 prior to component assembly and reflow heating. The PCB 100 contains a buried metal layer 102, a surface metal layer 106, and a dielectric 104 between the buried metal layer 102 and the surface metal layer 106. The dielectric 104 contains a blind via 108. The surface metal layer 106 extends along the sidewalls of the via 108 to contact the buried metal layer 102. The portion of the surface metal layer 106 in which the via 108 is disposed is a component contact pad 112. The solder paste 220 is disposed over the component pad and via 108. The solder paste 220 contacts the component pad 112 of the surface metal layer 106. The component pad 112 provides a mounting point for a component (not shown) to be mounted on the PCB 100 so that the component makes electrical contact with the buried metal layer 102. Although the solder paste 220 is intended to fill the via 108, in actuality the solder paste 220 tents over the via 108 such that the via 108 is only partially filled. The remainder of the via 108 forms a cavity 120 that contains air and volatiles.

When the PCB 100 is placed in a reflow oven to create a solder joint 222, air and volatile gasses vent into the solder joint 222 and cavity 120 in the via 108, getting trapped, and forming voids 230 that weaken the solder joint 222 as shown in FIG. 2. Micrographs of various void-filled solder joints formed by fusing printed solder paste and a Ball Grid Array (BGA) solder ball or using a Hot Air Solder Leveling (HASL) process show in each case the presence of large voids of different shapes in each solder joint.

One of the reasons that the cavity of the via remains unfilled is that the cavity of the via is not as solderable as the component contact pad. In addition, the structure may be contaminated with residual processing chemistry. Thus, the solder paste when applied or when heated to a molten state may not wet and fill the via. The resultant structure has a reduced contact area between the solder and the via and results in a mechanically weak structure. Solder joints are more likely to fail when thermally stressed if they contain voids. This situation is exacerbated if the currently-fashionable lead-free solders are used, as these solders are typically not as ductile as leaded solders. The use of lead-free solders further decreases the solder joint strength as the ultimate void formed is larger than that formed using leaded solder. The larger the void, the less reliable the solder joint. Specifically, voids greater than 36% (the percentage of the solder joint cross-sectional area occupied by the void) are beyond acceptable limits of most products as the solder joints fracture through the propagation of cracks. This leads to intermittent or failed connections to the components mounted to the PCB using the solder, and thereby creating unacceptable failure levels in products using the PCB.

As shown in FIG. 2, it is not uncommon for large voids to be present in the solder on component contact pads that contain blind vias. The proliferation of blind vias in component contact pad structures increases reliability risk of failure of the PCB for the above reasons. In one particular example, products with Ball Grid Arrays (BGAs) and Chip Scale Packages (CSPs) currently require tedious x-ray joint inspection to ensure reliability and conformance to the particular IPC-7095 Standard class (which categorizes void size for solder joints).

Filled vias, on the other hand, result in smaller and fewer voids, thereby increasing reliability. Thus, it is desirable to provide a method by which a blind via can be filled by solder.

### BRIEF DESCRIPTION OF THE DRAWINGS

Embodiments will now be described by way of example with reference to the accompanying drawings, in which:

FIG. 1 is a cross-sectional view of a known PCB coated with solder paste.

FIG. 2 is a cross-sectional view of the PCB of FIG. 1 after later processing.

FIG. 3 is a cross-sectional view of a PCB according to one embodiment.

FIG. 4 is a cross-sectional view of the PCB of FIG. 3 after removal of a portion of the top layer.

FIG. 5 is a cross-sectional view of the PCB of FIG. 4 in which a via is formed.

FIG. 6 is a cross-sectional view of the PCB of FIG. 5 after an electroless Cu layer is deposited.

FIG. 7 is a cross-sectional view of the PCB of FIG. 6 after a photoresist is deposited.

FIG. 8 is a cross-sectional view of the PCB of FIG. 7 after the photoresist is patterned.

FIG. 9 is a cross-sectional view of the PCB of FIG. 8 after a first plating layer is deposited.

FIG. 10 is a cross-sectional view of the PCB of FIG. 9 after a second plating layer of a low melting point metal is deposited.

FIG. 11 is a cross-sectional view of the PCB of FIG. 10 after the photoresist is removed.

FIG. 12 is a cross-sectional view of the PCB of FIG. 11 after the exposed metal of the top layer of the PCB is removed.

FIG. 13 is a cross-sectional view of the PCB of FIG. 12 after a second photoresist is applied.

FIG. 14 is a cross-sectional view of the PCB of FIG. 13 after the second photoresist is patterned.

FIG. 15 is a cross-sectional view of the PCB of FIG. 14 after a portion of the low melting point metal is removed.

FIG. 16 is a cross-sectional view of the PCB of FIG. 15 after the second photoresist is removed.

FIG. 17 is a cross-sectional view of the PCB of FIG. 16 in one embodiment after being removed from a reflow oven.

FIG. 18 is a cross-sectional view of the PCB of FIG. 17 after coating the PCB board with soldermask.

FIG. 19 is a cross-sectional view of the PCB of FIG. 18 after patterning the soldermask.

FIG. 20 is a cross-sectional view of the PCB of FIG. 19 after solder paste has been applied.

FIG. 21 is a cross-sectional view of the PCB of FIG. 20 after a ball grid array has been provided.

FIG. 22 is a cross-sectional view of the PCB of FIG. 21 after the PCB has been placed in a reflow oven.

FIG. 23 is a cross-sectional view of FIG. 16 after coating the PCB with soldermask but before reflowing the low melting point metal.

FIG. 24 is a cross-sectional view of the PCB of FIG. 6 in another embodiment after a plating layer has been deposited.

FIG. 25 is a cross-sectional view of the PCB of FIG. 24 after the low melting point metal has been deposited.

FIG. 26 is a cross-sectional view of the PCB of FIG. 25 after a photoresist has been deposited.

FIG. 27 is a cross-sectional view of the PCB of FIG. 26 after the photoresist has been patterned.

FIG. 28 is a cross-sectional view of the PCB of FIG. 27 after a portion of the exposed low melting point metal, first plating layer, electroless Cu layer, and surface metal have been removed.

FIG. 29 is a cross-sectional view of the PCB of FIG. 28 after the photoresist has been removed.

FIG. 30 is a cross-sectional view of the PCB of FIG. 29 after a second photoresist has been deposited.

FIG. 31 is a cross-sectional view of the PCB of FIG. 30 after the second photoresist has been patterned.

FIG. 32 is a cross-sectional view of the PCB of FIG. 31 after a portion of the low melting point metal has been removed.

FIG. 33 is a flow chart illustrating one embodiment of a method of forming blind vias filled with a fusible metal.

FIG. 34 is a flow chart illustrating another embodiment of a method of forming blind vias filled with a fusible material.

FIGS. 35A-35D are micrographs showing blind vias filled with eutectic solder using one of the embodiments.

FIG. 36 is a graph illustrating the component contact pad diameter vs. via depth.

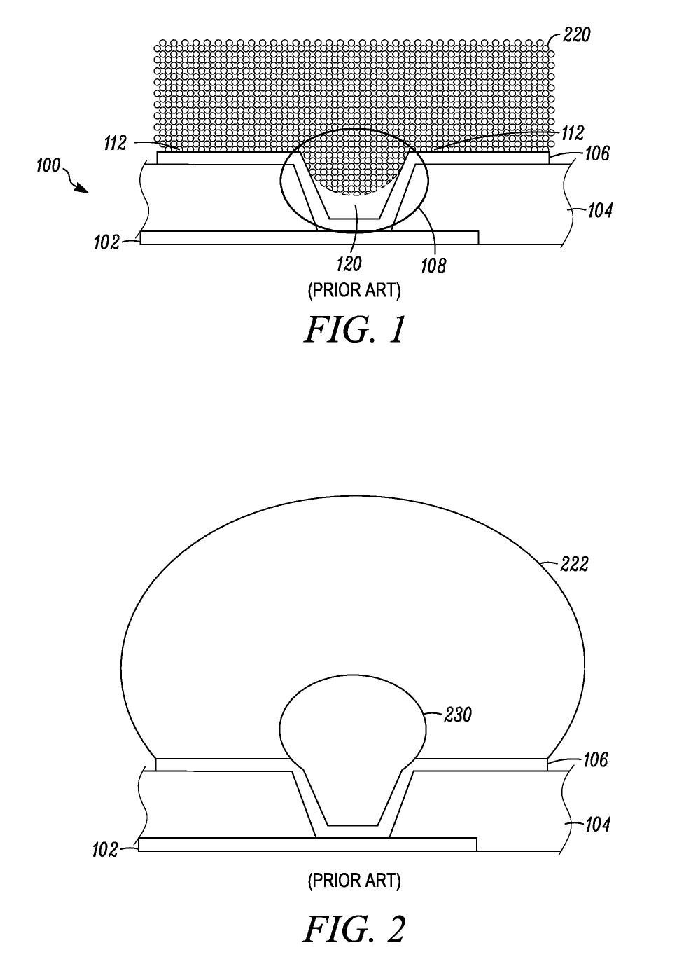

### DETAILED DESCRIPTION

A method of filling blind or buried vias in a PCB is disclosed. The vias are filled with fusible leaded or lead-free metal to reduce or eliminate large voids in solder joints. The blind via extends from a surface layer of the PCB (i.e., an outer exposed surface) to one of the buried layers while the buried via extends between buried layers. In neither case does the via extend all the way through the PCB. Focusing on the blind via, the blind via is formed in a component contact pad and is plated with a metal such as the material of the component contact pad prior to plating the fusible metal. The fusible metal in the via is then protected from removal while the remaining fusible metal is removed. After the protection is removed, flux is disposed in the via. The PCB is then heated until the fusible metal flows into the via. In this way, the number and size of the voids are decreased.

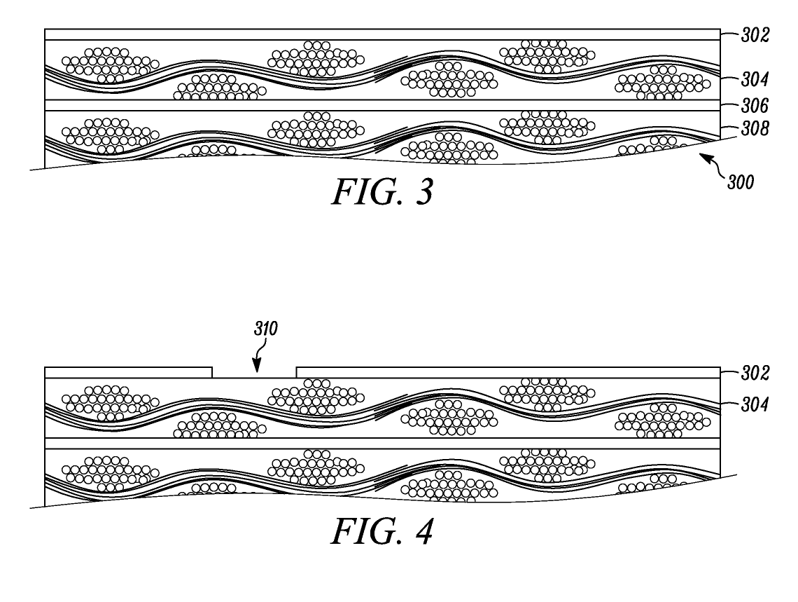

One embodiment by which blind vias are filled with material is provided in FIGS. 3-19. As shown in FIG. 3, the PCB 300 is a multilayer structure containing a top metal layer 302 (about 0.04 mils to about 0.5 mil typical thickness range), a buried metal layer 306 (about 0.2 mils to about 3 mils typical thickness range), a dielectric layer 304 (about 1 mil to about 10 mils typical range for blind vias) between the top metal layer 302 and the buried metal layer 306, a buried dielectric layer 308 (about 1 mil to about 20 mils typical range) beneath the buried metal layer 306, etc. . . . . The top and buried metal layers 302, 306 may be formed from any metal, leaded or lead-free, suitable for use in a PCB and may be the same or different. Different metals may be disposed on the same layer. For example, the top and buried metal layers 302, 306 may be formed from Cu. The dielectric layers 304, 308 may be the same or different. For example, dielectric layers 304 and 306 may be formed from FR4 epoxy glass. Different dielectrics may be used in between adjacent metal layers.

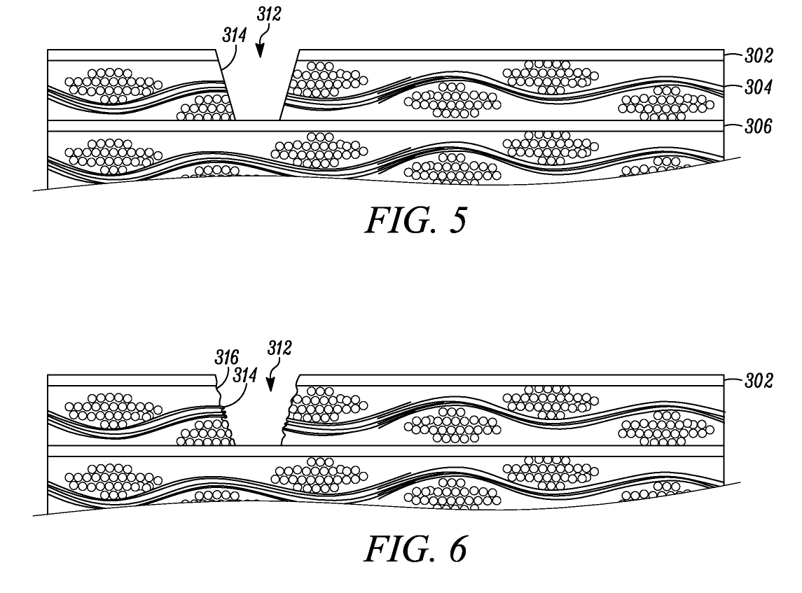

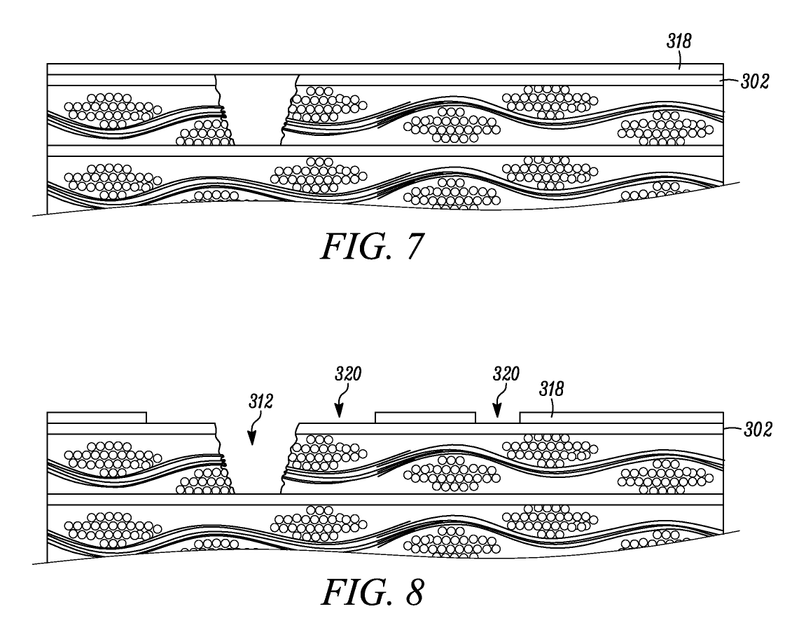

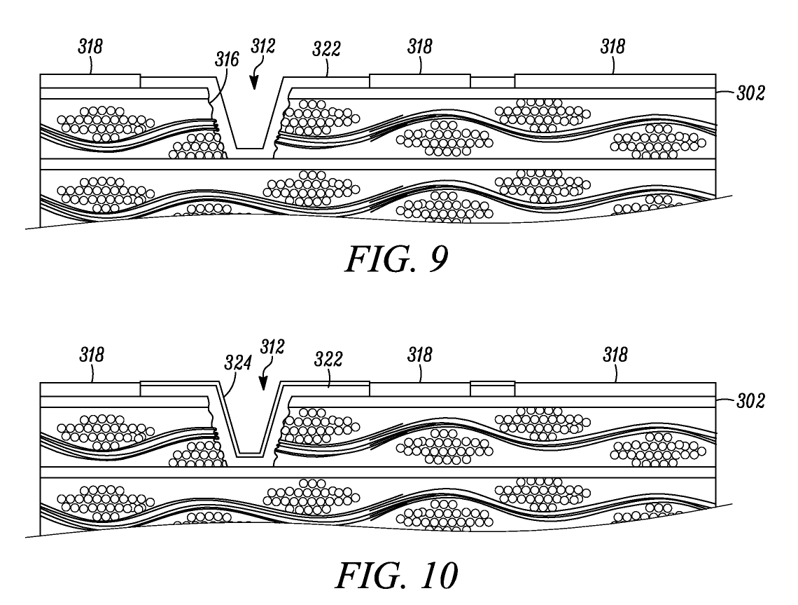

A portion of the top metal layer 302 is removed to form clearances 310 to expose the top of dielectric layer 304 as shown in FIG. 4. FIG. 5 illustrates removal of the exposed dielectric layer 304 to form a blind via 312. The resultant via 312 terminates at a target pad of the buried metal layer 306 and contains sidewalls 314. The via 312 is made conductive, plated such that a thin metallic layer 316 is disposed over the sidewalls 314 and the bottom of the via 312. As shown in FIG. 6, the preparation process may roughen the sidewalls 314 of the via 312 from the sidewalls formed, for example, during the ablation that created the via 312. As shown in FIG. 7, a photoresist 318 then deposited. The photoresist 318 is next patterned as shown in FIG. 8. Apertures 320 in the photoresist 318 expose the vias 312 and portions of the top metal layer 302. FIG. 9 illustrates that the exposed metal of the top metal layer 302 and the thin metallic layer 316 is then plated with a metal layer 322. A low melting point metal 324 is then pattern plated on the plating metal layer 322 as shown in FIG. 10. As illustrated in FIGS. 9-10, the plating attaches to the exposed metal layers but does not adhere to the photoresist 318. Note that the PCB 300 may contain multiple blind vias as well as multiple plated through holes (and multiple buried vias), which are not shown for convenience. The through holes and blind vias may be plated simultaneously or independently.

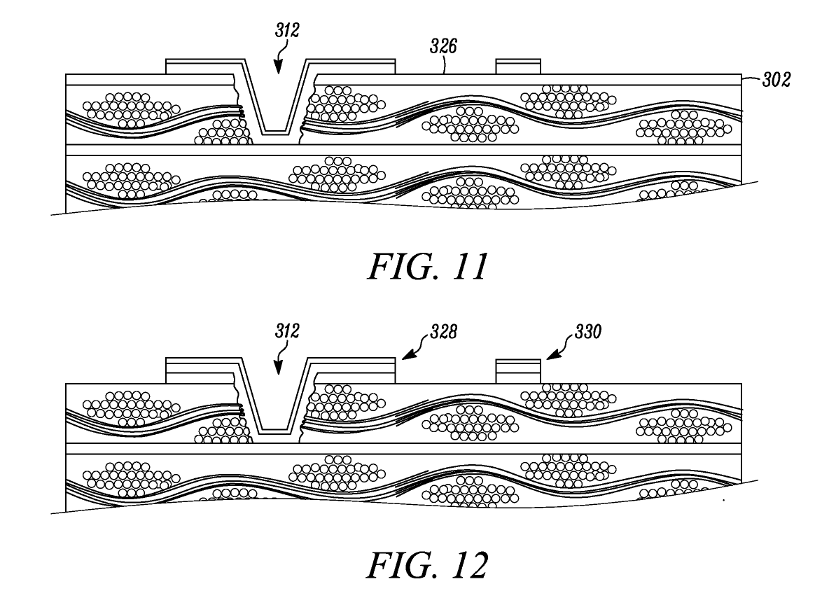

Once the low melting point metal 324 is deposited, the photoresist 318 is stripped from the PCB 300. This exposes a portion of the top metal layer 302 as shown in FIG. 11. The exposed portion 326 of the top metal layer 302 is then removed to form component contact pads 328 and other circuitry 330 on the top of the PCB 300 as shown in FIG. 12. The component contact pads 328 can be isolated lands or connected along the top metal layer 302 (or along a buried layer) to other circuitry on the top metal layer 302. The low melting point metal 324 acts as an etch resist when the top metal layer 302 or the plating metal layer 322 is etched. The component contact pads 328 and other circuitry 330 on the top of the PCB 300 contain the top metal layer 302, the thin metallic layer 316, the plating metal layer 322, and the low melting point metal 324.

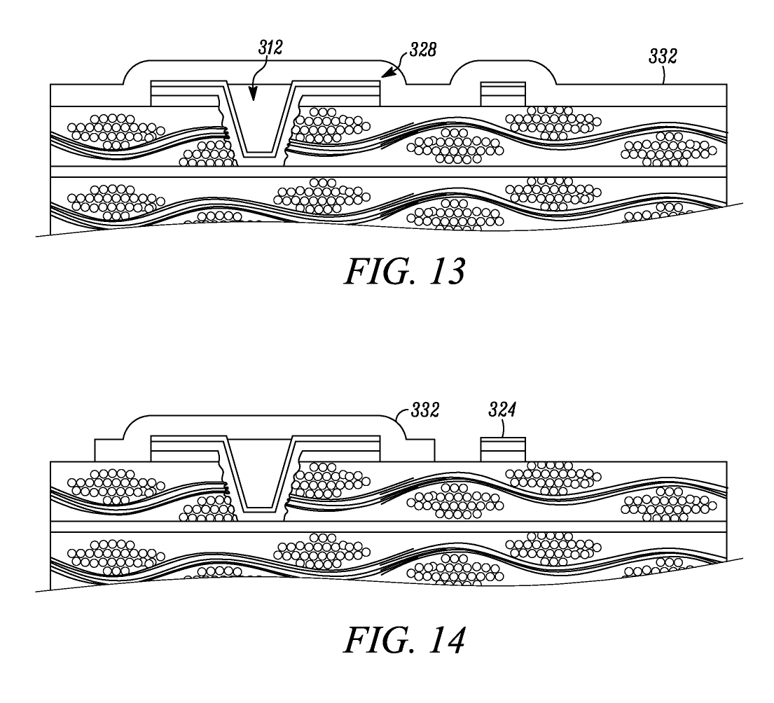

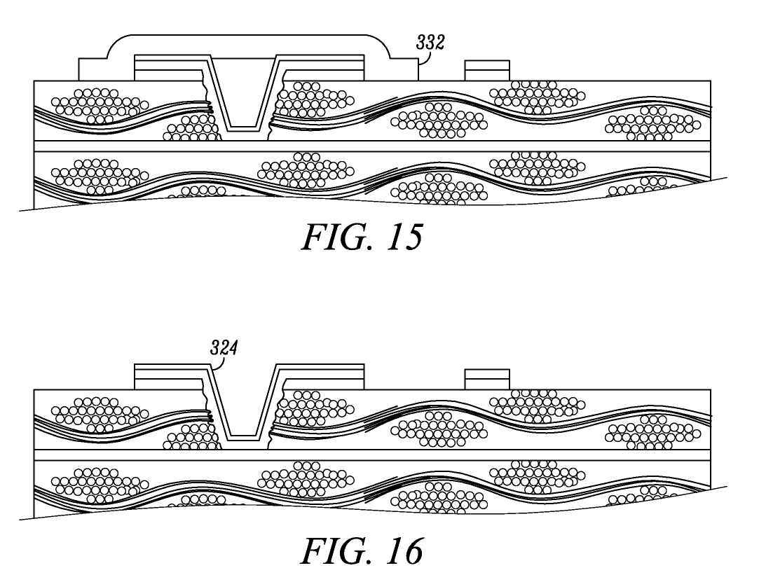

A protectant such as a photoresist 332 is deposited on the component contact pads 328 containing the vias 312 as shown in FIG. 13. The photoresist 332 may be, for example, a dry film formed of a polymer that is applied to the entire PCB 300 and a vacuum sealed on the PCB 300. Note that all of the photoresists used herein are depicted as being dry photoresists that are laminated on the underlying structure (e.g., using a roll process). However, other types of photoresists may be used. A pattern is then imaged on the photoresist 332 using a mask and the unexposed photoresist 332 removed in an alkaline developer as shown in FIG. 14. The low melting point metal 324 that remains uncovered by the photoresist 332 is then removed, leaving the structure shown in FIG. 15.

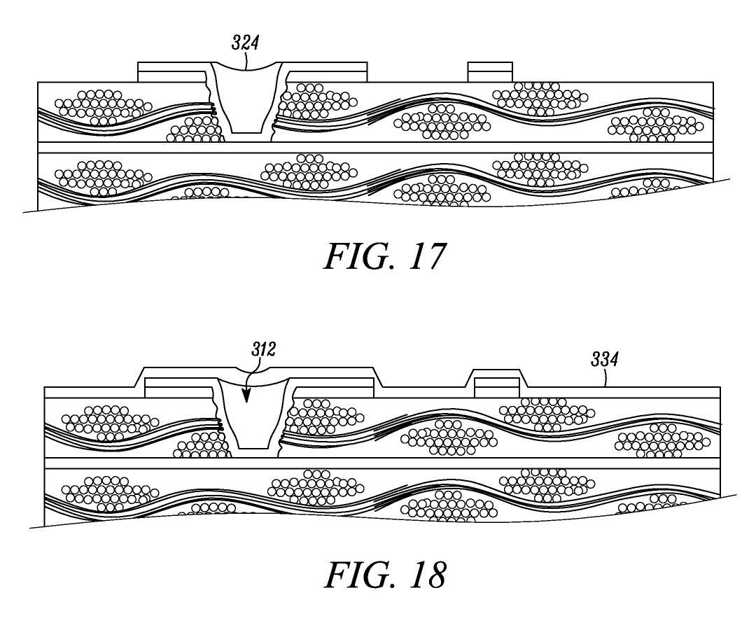

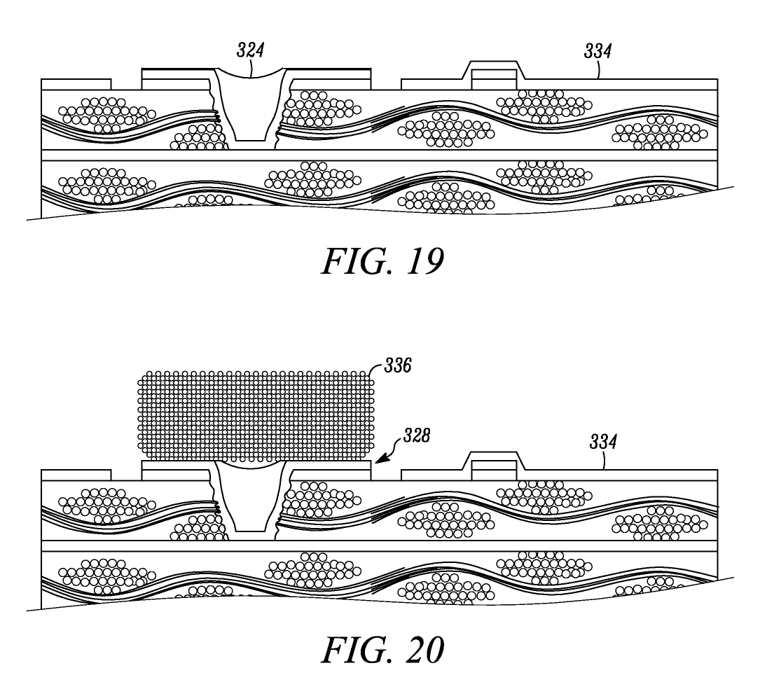

After the uncovered low melting point metal 324 is removed, the remaining photoresist 332 is then removed as shown in FIG. 16, and flux (not shown) is applied to the via. After the flux has been applied, the structure is then placed into a reflow oven, where the low melting point metal 324 remaining on the structure reflows as shown in FIG. 17. The use of flux helps to even out the heat in the PCB 300. The low melting point metal 324 on the component contact pad 328 is drawn into the via 312 by surface tension such that the via 312 is filled with the low melting point metal 324 as shown in FIG. 17. The PCB 300 is cleaned to remove the flux using standard cleaning processes and a soldermask 334 (about 0.1 mil to about 1 mil typical thickness range) is applied to the PCB 300 as shown in FIG. 18. The soldermask 334 may be formed from a photosensitive material that adheres to the PCB 300 such as epoxy or some other acrylate based material. The soldermask 334 is then patterned as shown in FIG. 19. In this embodiment, the via 312 is filled before the soldermask 334 is applied to the PCB 300. This may help prevent soldermask coating defects such as air bubbles from air trapped in tented and unfilled blind vias. The soldermask 334 acts as a protecting layer to provide electrical insulation and limit solder flow. The soldermask 334 can be applied by screen printing, curtain coating, dip coating, sprayed on if the soldermask 334 is initially in liquid form, or, if the soldermask 334 is in dry form, it can be vacuum laminated on.

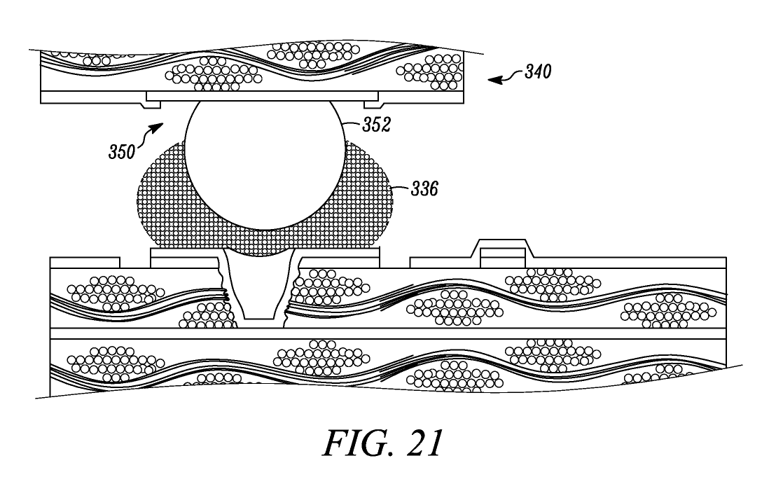

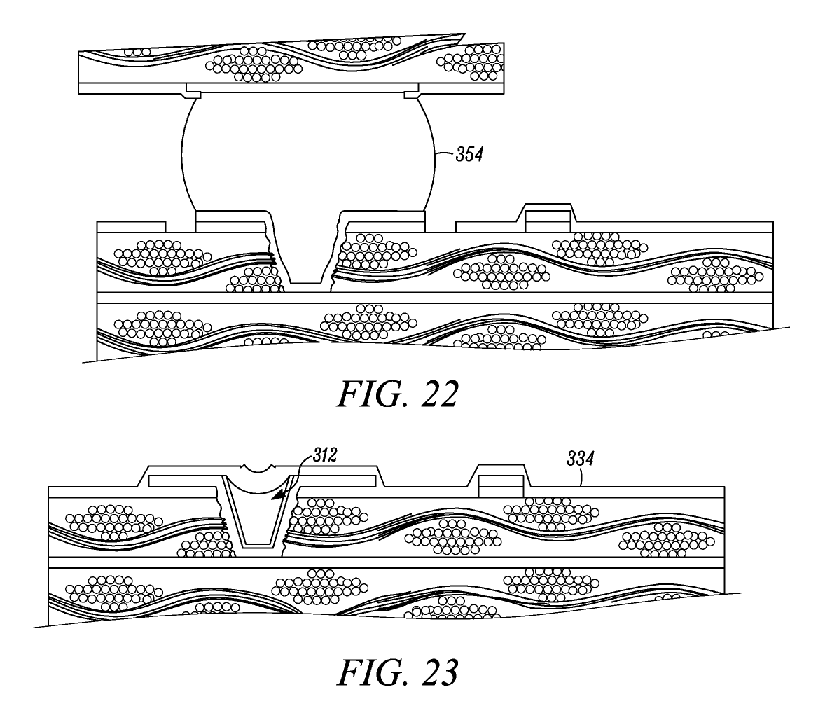

After the soldermask 334 is patterned on the PCB 300, solder paste 336 is applied to the PCB 300. The solder paste 336 adheres to exposed metal on the surface of the PCB 300. Thus, as shown in FIG. 20, the solder paste 336 is disposed on the component contact pads 328 and the via 312. After the solder paste 336 is disposed on the component contact pads 328 and the via 312, a component may be attached to the solder paste 336. For example, a package 340 containing a BGA 350 may be attached as shown in FIG. 21. As illustrated, the BGA 350 contains a solder ball 352 which is applied to the PCB 300 such that the solder ball 352 makes contact with the solder paste 336. The resulting combined structure is then placed in a reflow oven where the solder ball 352 and solder paste 336 flow and merge with the low melting point metal 324 in the via 312 into a large solder ball 354 which is allowed to cool and harden as shown in FIG. 22. This provides permanent attachment between the PCB 300 and the package 340. Note that if solder paste 336 is slightly misregistered, overlapping the soldermask 334, during reflow surface tension pulls the solder paste 336 back to the component contact pads 328.

In a different embodiment, the soldermask 334 is deposited on the PCB 300 before the flux is applied and the low melting point metal 324 flows into the via 312. FIG. 23 illustrates the unpatterned soldermask 334 coated PCB 300 before the low melting point metal 324 flows into the via 312, i.e., after FIG. 16. Thus, in this embodiment, the via 312 is filled after the soldermask 334 is applied. The process then proceeds as shown in FIG. 19. This may help to prevent soldermask coating defects from flux residues.

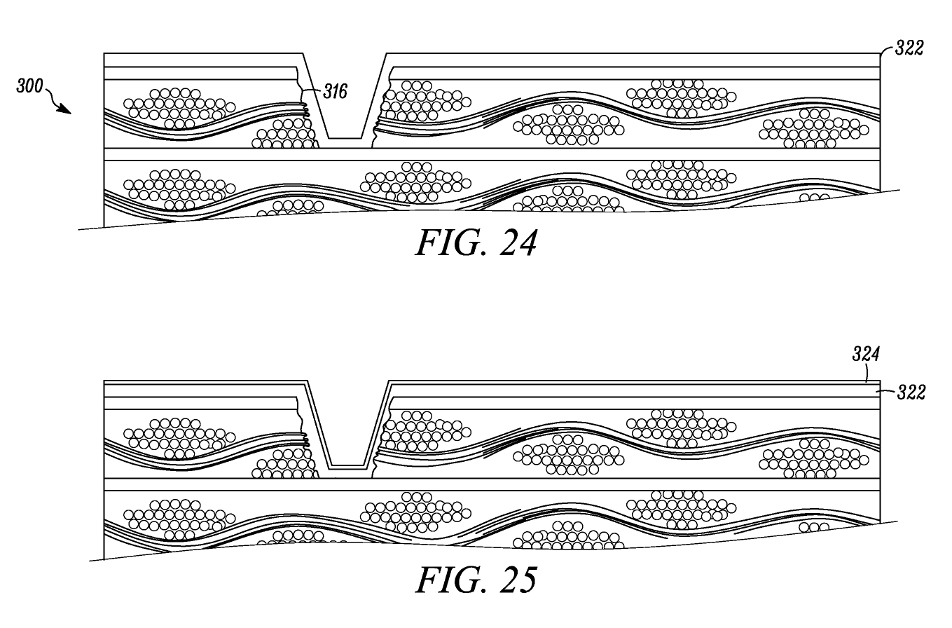

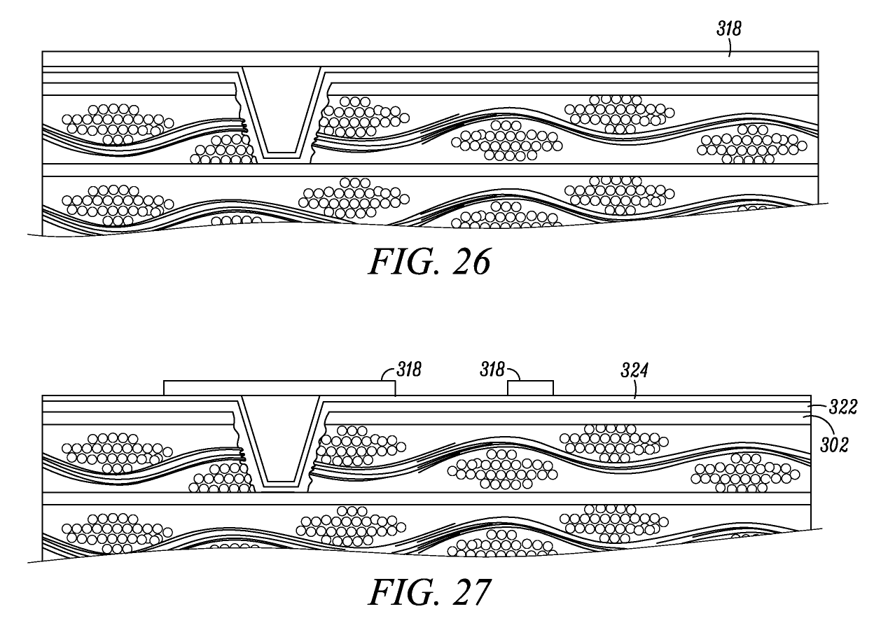

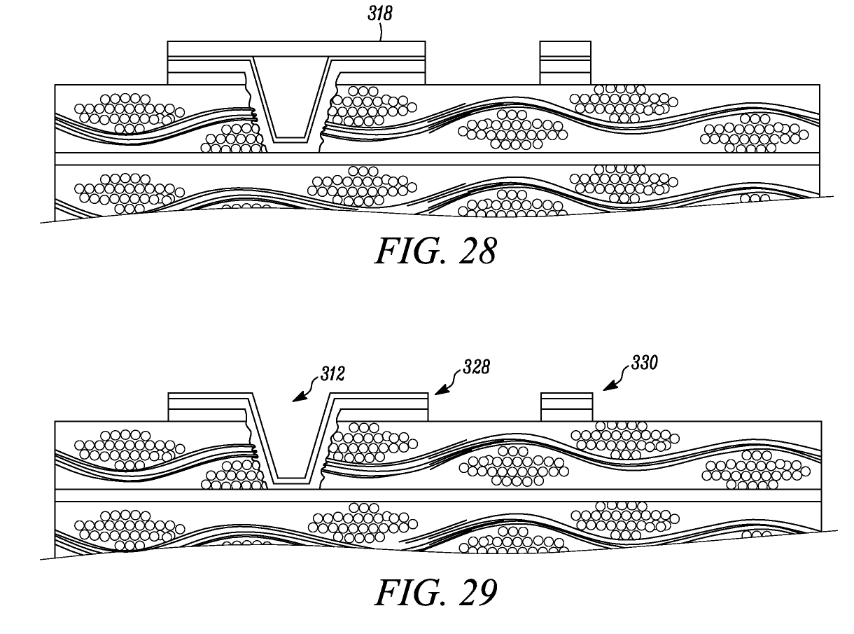

The embodiment shown in FIGS. 24-32 show another embodiment after the thin metallic layer 316 is applied as shown in FIG. 6. In FIG. 24, the plating metal layer 322 is applied to the entire PCB 300 by panel plating and everywhere covers the thin metallic layer 316. In FIG. 25, the low melting point metal 324 is next applied to the entire PCB 300 by panel plating and everywhere covers the plating metal layer 322. A photoresist 318 is applied to the entire PCB 322 as shown in FIG. 26 and then imaged and developed as above, as shown in FIG. 27. The exposed low melting point metal 324, the plating metal layer 322 underlying the exposed low melting point metal 324, and the thin metallic layer 316 underlying this portion of the plating metal layer 322, and the top metal layer 302 underlying the thin metal layer 316 are then removed as shown in FIG. 28. The photoresist 318 is then stripped after the exposed layers are removed leaving the structure shown in FIG. 29.

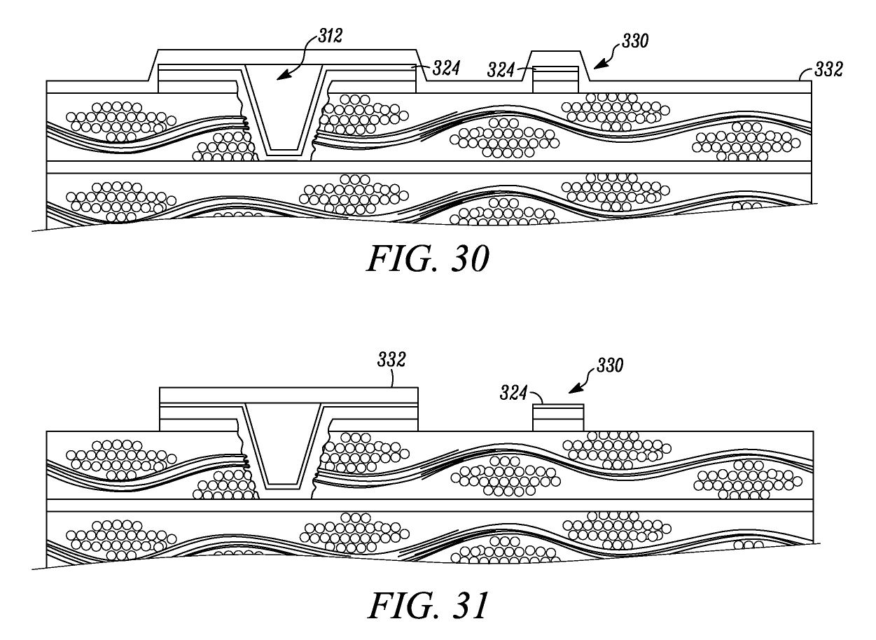

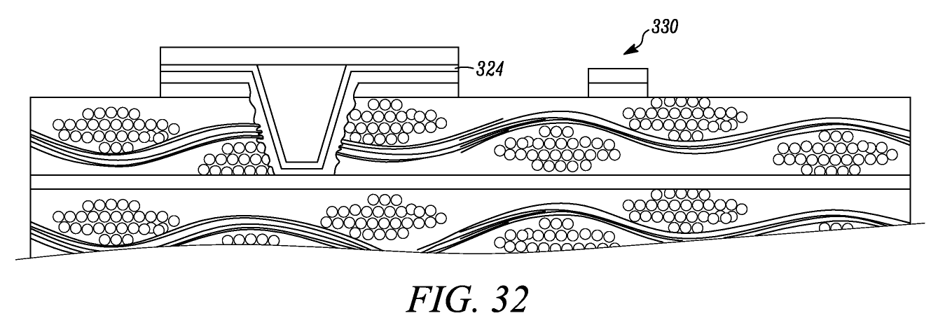

Note that in this embodiment, the low melting point metal 324 remains on the other circuitry 330 as shown in FIG. 29 and may be removed later, before reflow, if desired. In FIG. 30, a photoresist 332 is deposited on the via 312 and the other circuitry 330, both of which contain the low melting point metal 324. The photoresist 332 is then patterned to remove the photoresist 332 from the other circuitry 330 as shown in FIG. 3 1. The exposed low melting point metal 324 on the other circuitry 330 is then removed as shown in FIG. 32, the remaining resist is stripped, and the process then continues as shown in FIG. 16.

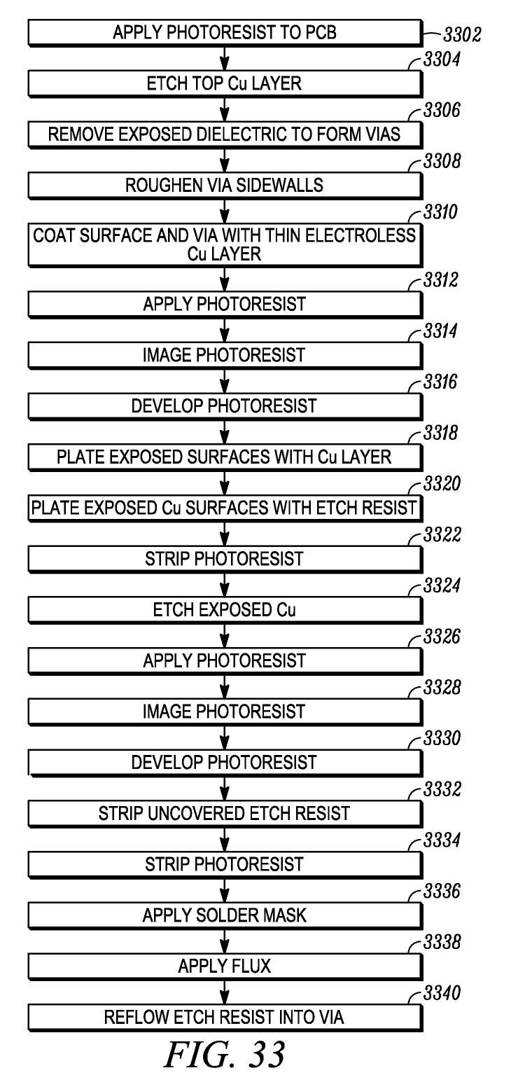

A flowchart of one embodiment of filling a blind via is shown in FIG. 33. In FIG. 33, the top metal layer, thin metallic layer, and plating metal layer are described as all being formed from Cu. In this figure, initially, a mask is applied to the PCB and the top Cu layer (3302). The top Cu layer is chemically or mechanically etched using the mask to open up holes in the top Cu layer to expose portions of the underlying dielectric (3304). The exposed dielectric is then removed to form a via to a target pad (3306). The top Cu layer may be removed by laser (e.g., UV or CO₂ laser) or sputter ablation, controlled depth mechanical drilling, sandblasting, chemical etching or any other known method. The exposed dielectric may be removed by laser (e.g. UV or CO₂ laser) or plasma ablation, controlled depth mechanical drilling, sandblasting, chemical etching or any other known method. Some methods of mechanical removal of the top Cu layer and/or dielectric may not use a mask. If a UV laser is used, the Cu and dielectric may be removed in a single step. The diameter of the opening at the top of the via adjacent to the top Cu layer may be, for example, about 1-12 mils, typical of fine pitch arrays. The PCB is chemically treated (3308) to desmear the via. This roughens the sidewalls of the via and allows for better adhesion of conductive layers to the sidewalls.

After roughening the sidewalls, the PCB is disposed in Cu plating solution. A thin Cu layer about 10 microinches to 200 microinches is then deposited using an electroless method (33 10). Unlike general plating techniques, in the electroless method, current is not applied to the bath. Thus, the Cu layer that forms is relatively thin and controllable. The thin Cu layer electrically connects the top Cu layer to the target pad of the buried Cu layer.

A photoresist is then deposited on the structure (3312). The photoresist is imaged (3314) using a photomask or laser direct imaging and subsequently developed (3316) to form a patterned photoresist. The photoresist-covered PCB is then submerged in another Cu plating solution. The regions of the PCB that are exposed are all formed from Cu. Current is passed through the plating solution to create a Cu plating layer that is thicker, about 0.6 mils to about 3 mils, than the electroless plating layer (3318). The Cu plating layer is formed only where other Cu layers present, not where the photoresist is disposed.

The PCB containing the plated Cu layer is then removed from the Cu plating solution. The PCB is then placed in another plating bath where a second metal layer is plated on the plated Cu layer (3320). The second metal layer may be a low melting point metal, for example, a eutectic solder metal etch resist or fusible equivalent such as Sn. Examples of eutectic solder include Sn_{0.6}/Pb_{0.4}, Sn_{0.63}/Pb_{0.37}, or lead-free solders. The lead-free solders may include Sn, Cu, Ag, Bi, In, Zn, or Sb. Commonly used lead-free solders include: SnAg_{3.0}Cu_{0.5}, SnAg_{3.5}Cu_{0.7}, SnAg_{3.5}Cu_{0.9}, SnAg_{3.8}Cu_{0.7}, SnAg_{3.8}Cu_{0.7}Sb_{0.25}, SnAg_{3.9}Cu_{0.6}, SnCu_{0.7}, SnZn₉, SnZn₈Bi₃, SnSb₅, SnAg_{2.5}Cu_{0.8}Sb_{0.5}, SnIn_{8.0}Ag_{3.5}Bi_{0.5}SnBi_{0.5}, SnBi₅₇Ag₁, SnBi₅₈, and SnIn₅₂, which have melting points between about 120° C. and about 240° C. The plated thickness ranges from about 0.1 mil to about 1 mil, but is typically about 0.4 mils.

After the second metal layer is plated on the PCB, the PCB is removed from the bath. Panel plating can be used to plate both the Cu layer and metal etch resist. In any case, the plating sequence is not interrupted so the vias stay wet and excellent metal etch coverage is obtained in the cavities of the vias. The photoresist is then stripped (3322) and the exposed Cu subsequently etched (3324) in a selective etch, for example a pH buffered ammoniacal etch solution. The selective etch removes Cu but not the plated metal etch resist. The remaining structures on the top of the PCB (e.g., the contact to the via and other circuitry) and at the bottom of the via contain multiple Cu layers: the original Cu layer, the electroless Cu, and the plated Cu layer. The sidewalls of the via contain the electroless Cu and the plated Cu layer. Each of these structures also contains the plated metal etch resist.

Another resist is vacuum laminated onto the PCB (3326) and then patterned (3328) and developed (3330) such that the resist covers the via and associated component contact pad. The resist may be photosensitive and thus exposed and developed in processes similar to the other photoresist, albeit using different chemistries. The resist is patterned to protect the plated metal etch resist on the via and the component contact pad. The unprotected plated metal etch resist is stripped using a selective etch (3332) for example nitric acid or ferric/nitric acid based solutions or fluoride, fluorborate, and peroxide based solutions. The selective etch removes the plated metal etch resist but not Cu or the photoresist. The photoresist is then stripped (3334).

A soldermask is applied to the PCB (3336). Flux is then applied through the mask (3338). The PCB is placed in an oven. The temperature in the oven is high enough to allow the plated etch resist to flow or fuse (3340) but low enough to not harm the PCB. The PCB remains in the oven for long enough to allow the plated etch resist to fuse and fill the blind vias. The molten etch resist fills the via because the surface tension draws the etch resist into the via. The via is not tented by the etch resist, thereby providing an escape path for volatiles to vent as the molten etch resist fills the via. The via may be formed, for example, using Sn, which permits the via cavity to be solderable. The PCB is then removed from the oven and allowed to cool. If desired, the flux may be applied without the soldermask being present.

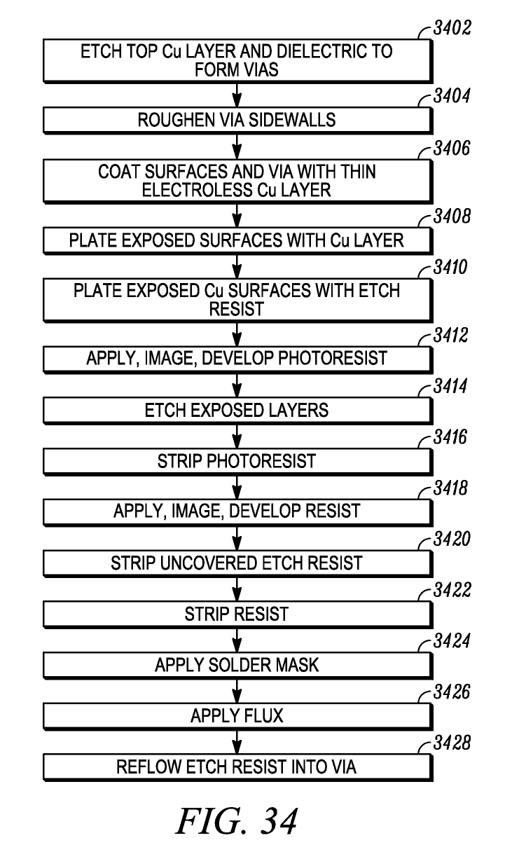

Another embodiment of a more in-depth process of creating a void-free blind via is shown in FIG. 34. In FIG. 34, the top metal layer, thin metallic layer, and plating metal layer are all Cu. Initially, the top Cu layer and dielectric are etched to form a via to the target pad (3402). The PCB is treated to roughen the sidewalls of the via (3404). A thin Cu layer is then plated (3406). The PCB is placed in a different Cu plating bath and a thicker Cu layer then plated on the thin Cu layer (3408). The PCB is then placed in a plating bath containing a different solution and the fusible metal (i.e., the metal etch resist) is plated (3410). The PCB may be moved from the Cu bath, rinsed (e.g., with deionized water), and transported to the fusible metal bath without drying the PCB. After being removed from this latter plating bath, a photoresist is then deposited on the structure, imaged, and developed (3412) to form a patterned photoresist. The exposed portion of the fusible metal layer and the underlying Cu layers are subsequently etched (3414) in different etches as previously described to the dielectric. Alternately a dry etch process may be used. The photoresist is stripped (3416). Another photoresist is then laminated onto the PCB and is patterned via photolithographic processes (3418) such that the resist covers the via and associated component contact pad. The unprotected plated metal etch resist is stripped using a selective etch (3420) and the photoresist is then stripped (3422). A soldermask is applied to the PCB (3424). Flux is next applied (3426) and the fusible material heated to a temperature sufficient to allow the material to flow or fuse (3428). If desired, the flux may be applied without the soldermask being present.

Solder is applied to the PCB 300 containing filled blind vias to affix components to the PCB 300. To apply the solder, a stencil (about 1 mil to about 6 mils typical thickness range) on which solder paste (about 1 mil to about 6 mils typical thickness range) is disposed is placed on the PCB 300 such that intimate contact between the stencil and the PCB 300 is established. The stencil has a pattern containing apertures through which the solder paste will be applied to the PCB 300. The pattern can be preformed and the stencil aligned on the PCB 300 or can be formed using a photolithographic process similar to that described above. After the stencil is placed on the PCB 300, a spreader is moved along the stencil, spreading a layer of the solder paste along the stencil and through the apertures onto the PCB 300. The stencil is then removed from the PCB 300, leaving the solder paste. The solder paste can be disposed on the filled blind via 350 or at other locations of the PCB 300. As indicated above, the soldermask is already disposed on the PCB 300 and protects the portions covered thereby from the solder paste. Components are then disposed on the PCB 300 at least some of the solder locations and the PCB 300 placed in a reflow oven to permit the solder to permanently bond the components to the PCB 300.

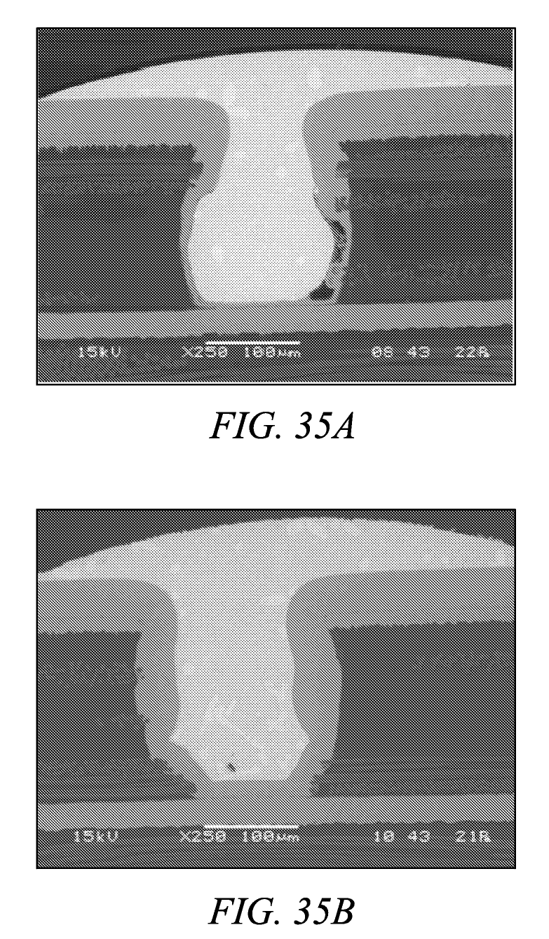

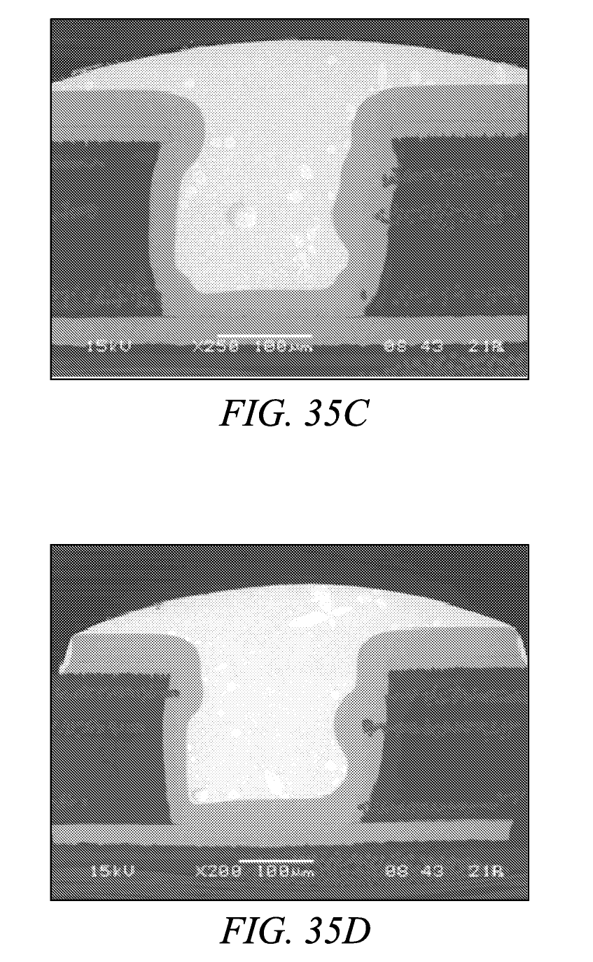

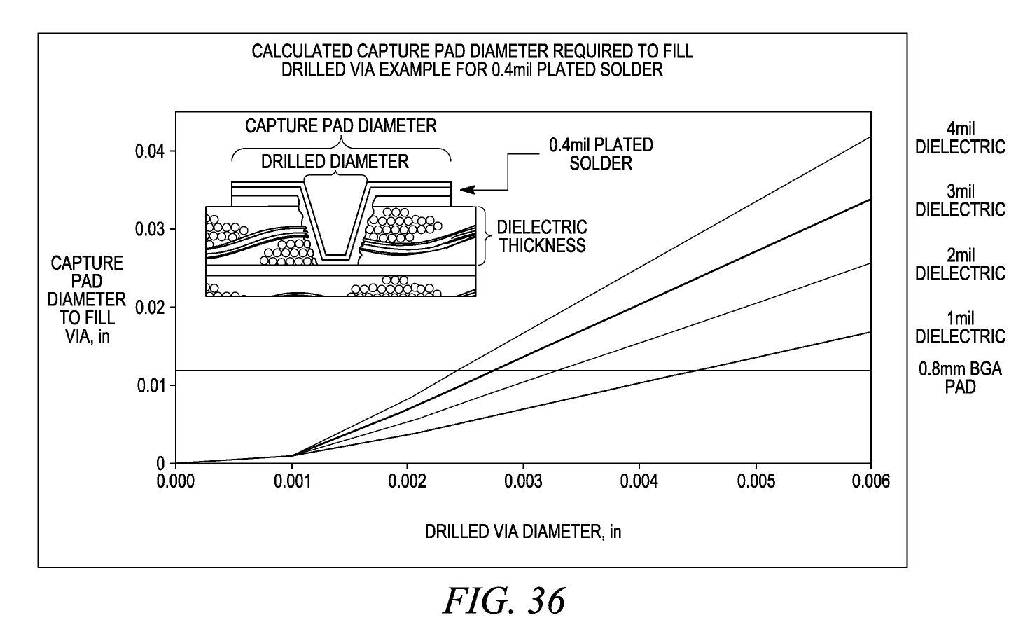

The described techniques may permit a greater design flexibility in the component contact pad and via dimensions than that permitted for blind vias containing solder or only plated metal, as well as using less complex and costly method steps. FIGS. 35A-35D are micrographs showing blind vias filled with eutectic solder using the above methods. Note that although the blind vias shown in FIGS. 35A-35D have different diameters, about 6 mils, about 8 mils, about 10 mils, and about 12 mils respectfully, they are all filled and contain few, if any, large voids. A calculated graph of component contact (capture) pad diameter vs. via depth is depicted in FIG. 36. Specifically, this graph shows, for a set etch resist thickness on the capture pad, the capture pad diameter to fill a particular via depth. Thus, the thickness of the etch resist to fill the via to a predetermined level may be determined prior to applying the etch resist to the via and component contact pad using the surface area of the component contact pad and the depth of the via.

While the above technique describes various methods of filling the blind via, other techniques of reducing the cavity may be used in addition to the above. For example, the via diameter may be increased, which may decrease the air pocket. Alternatively, the via may be offset from the component contact pad to avoid trapping air. However, such approaches may not be practical in some circumstances, e.g., providing blind vias in component contact pads is a space saving feature that is used in fine pitch BGAs and CSPs.

The method of filling a blind via described above avoids several problems that may be present elsewhere. For example, while other methods encounter problems in displacing the air in the via when filling the via, the described method may avoid such a problem. If the material that fills the via is solderable, a cap layer may be eliminated if desired. The material that fills the via also has good adhesion to the underlying sidewall layer, even after being thermally stressed. Further, although multiple etch resist layers can be plated in the via, only one layer may be used and chemical thinning of this layer may be avoided. The via may be filled without using pulse panel plating, which uses a separate plating setup, unlike when the via is filled with the same material as the component contact pad using plating. Nor is the via limited to small shallow vias with smooth, well-defined geometry as in some other methods. Further, unlike other methods, the present methods permit the via simultaneously with a through hole. Note that although a blind via between the surface and a buried layer is described, in other embodiments, the disclosed method can create blind vias that connect buried layers together without extending the via fill to the surface to provided stacked connections (which, as above, can be plated in-situ with through holes).

It will be understood that the terms and expressions used herein have the ordinary meaning as is accorded to such terms and expressions with respect to their corresponding respective areas of inquiry and study except where specific meanings have otherwise been set forth herein. Further, although the singular term has been used throughout the specification to describe various features, multiples of these features are intended to be encompassed. Relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

Those skilled in the art will recognize that a wide variety of modifications, alterations, and combinations can be made with respect to the above described embodiments without departing from the spirit and scope of the invention defined by the claims, and that such modifications, alterations, and combinations are to be viewed as being within the purview of the inventive concept. Thus, the scope of the present invention should therefore not be limited by the embodiments illustrated.

1. A method of filling a blind via in a printed circuit board (PCB), the method comprising:
covering sidewalls of the blind via with a conductor;
coating the via with a metallic etch resist, the etch resist having a lower melting point than the conductor covering the sidewalls of the via;
protecting the metallic etch resist with a protectant;
removing the metallic etch resist from the PCB at locations other than those protected by the protectant;
removing the protectant after the metallic etch resist has been removed from the PCB at locations other than those covered by the protectant; and
heating the PCB after the protectant has been removed enough to melt the metallic etch resist, the molten metallic etch resist flowing into the via.

2. The method of claim 1, further comprising forming the via in a component contact pad that is formed from a lead-free material.

3. The method of claim 1, wherein the covering and coating of the via each comprises plating the via.

4. The method of claim 3, further comprising forming the via in a component contact pad, the component contact pad being formed from the conductor, wherein the PCB is not dried between the plating and the coating.

5. The method of claim 1, wherein protecting the metallic etch resist with a protectant comprises laminating a photoresist over the via containing the metallic etch resist.

6. The method of claim 1, further comprising providing solder on the PCB after removing the protectant and before heating the PCB.

7. The method of claim 1, wherein the via extends between a surface of the PCB and a buried metal layer of the PCB.

8. A printed circuit board (PCB) comprising:
a dielectric through which a blind via extends, the via having sidewalls that are coated with a conductor and a metallic etch resist having a lower melting point than the conductor, the conductor more proximate to the sidewalls than the metallic etch resist; and
a laminate photoresist disposed over the via.

9. The PCB of claim 8, further comprising a component contact pad in which the via is disposed, the component contact pad disposed on the dielectric, the component contact pad containing the conductor and the metallic etch resist, the metallic etch resist more distal from the dielectric than the conductor, the photoresist disposed on the component contact pad.

10. The PCB of claim 8, wherein the conductor comprises a multilayer plated structure of different thicknesses and formed from the same material.

11. The PCB of claim 8, wherein the via extends between a surface of the PCB and a buried metal layer of the PCB.

12. The PCB of claim 8, further comprising a through hole coated with the conductor and the metallic etch resist.

13. The PCB of claim 8, further comprising circuitry on the dielectric, the circuitry formed from the conductor but without the metallic etch resist and photoresist.

14. A method of filling a blind via in a printed circuit board (PCB), the method comprising:
covering sidewalls of the blind via in a component contact pad with a conductor, the component contact pad formed from the conductor;
coating the covered via and component contact pad with a metallic etch resist, the etch resist having a lower melting point than the conductor;
laminating a photoresist on the coated via and component contact pad;
removing the metallic etch resist from the PCB at locations other than those protected by the photoresist;
removing the photoresist after the removing of the metallic etch resist; and
heating the PCB after the photoresist has been removed enough to melt the metallic etch resist to allow the molten metallic etch resist to flow from the component contact pad into the via and fill the via.

15. The method of claim 14, wherein the coating of the covered via and component contact pad comprises determining a thickness of the metallic etch resist to fill the via to a predetermined level using a surface area of the component contact pad and a depth of the via prior to applying the metallic etch resist to the covered via and component contact pad.

16. The method of claim 14, further comprising performing the covering and coating without permitting the PCB to dry there between.

17. The method of claim 14, further comprising providing solder on the PCB after the removing of the photoresist and before the heating of the PCB.

18. The method of claim 14, further comprising providing solder on the PCB after the heating of the PCB.
